(19) United States
(12) Patent Application Publication
(10) Pub. No.: US 2023/0377879 A1
(43) Pub. Date: Nov. 23, 2023

(54) BARRIER LAYER FOR PREVENTING ALUMINUM DIFFUSION

(71) Applicant: Applied Materials, Inc., Santa Clara, CA (US)

(72) Inventors: Srinivas Gandikota, Santa Clara, CA (US); Elizabeth Mao, San Jose, CA (US); Tianyi Huang, Santa Clara, CA (US); Tengzhou Ma, San Jose, CA (US); Chi-Chou Lin, San Jose, CA (US); Yixiong Yang, Fremont, CA (US)

(73) Assignee: Applied Materials, Inc., Santa Clara, CA (US)

(21) Appl. No.: 17/747,978

(22) Filed: May 18, 2022

(51) Int. Cl. H01L 21/02

(52) U.S. Cl. CPC H01L 21/02362; H01L 21/02153; H01L 21/02181

(57) ABSTRACT

Embodiments of the present disclosure are related to methods of preventing aluminum diffusion in a metal gate stack (e.g., high-κ metal gate (HKMG) stacks and nMOS FET metal gate stacks). Some embodiments relate to a barrier layer for preventing aluminum diffusion into high-κ metal oxide layers. The barrier layer described herein is configured to reduce threshold voltage (Vₜ) shift and reduce leakage in the metal gate stacks. Additional embodiments relate to methods of forming a metal gate stack having the barrier layer described herein. The barrier layer may include one or more of amorphous silicon (a-Si), titanium silicon nitride (TiSiN), tantalum nitride (TaN), or titanium tantalum nitride (TiTaN).

### TECHNICAL FIELD

Embodiments of the present disclosure generally relate to methods of preventing aluminum diffusion into an underlying metal layer. In particular embodiments, a barrier layer is formed on a metal gate stack (e.g., a high-κ metal gate (HKMG) stack) for preventing aluminum diffusion.

### BACKGROUND

Semiconductor technology has advanced at a rapid pace and device dimensions have shrunk with advancing technology to provide faster processing and storage per unit space.

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased. Therefore, as semiconductor technology advances, the market demands increasing smaller chips with increasingly more structures per unit area.

As device dimensions have shrunk, device geometries and materials have experienced difficulty maintaining switching speeds without incurring failures. Several new technologies emerged that allowed chip designers to continue shrinking gate lengths. Control of the dimensions of device structure is a key challenge for present and future technology generations. Since 1970, the number of components per chip has doubled every two years. As a consequence of this trend, the miniaturization of circuits by scaling down the transistor has been the principal driver for the semiconductor technology roadmap.

There are challenges associated with threshold voltage (Vₜ) shift and leakage due to aluminum diffusion into high-κ metal oxide layers of metal gate stacks (e.g., high-κ metal gate (HKMG) stacks). The Vₜ tuning range will be limited by the thickness variation with further scaling down of device sizes. Some metal gate stacks include a high-κ capping layer comprising titanium nitride (TiN) as a protective layer. However, high-κ titanium nitride (TiN) capping layers typically do not prevent aluminum diffusion, thus resulting in undesired Vₜ shift and leakage.

Therefore, there is a need in the art for a barrier layer for improving threshold voltage (Vₜ) and substantially preventing leakage.

### SUMMARY

One or more embodiments of the disclosure are directed to a method of preventing aluminum diffusion in a metal gate stack. In some embodiments, the method comprises forming a high-κ barrier layer on an underlying metal layer. The high-κ barrier layer comprises one or more of amorphous silicon (a-Si), titanium silicon nitride (TiSiN), tantalum nitride (TaN) or titanium tantalum nitride (TiTaN) and has a thickness in the range of 5 Å to 30 Å. The method further comprises depositing an aluminum-containing layer on the high-κ barrier layer. In some embodiments, substantially no aluminum from the aluminum-containing layer migrates through the barrier layer into the underlying metal layer.

Additional embodiments of the disclosure are directed to a metal gate stack comprising: an interfacial silicon oxide layer on a substrate surface; a high-κ metal oxide layer on the interfacial silicon oxide layer; a high-κ barrier layer on the high-κ metal oxide layer; and an aluminum-containing layer on the high-κ barrier layer.

Further embodiments are directed to a method of forming a metal gate stack. In one or more embodiments, the method comprises depositing an interfacial silicon oxide layer on a substrate surface; forming a high-κ metal oxide layer on the interfacial silicon oxide layer; depositing a high-κ barrier layer on the high-κ metal oxide layer; depositing an aluminum-containing layer on the high-κ barrier layer; optionally depositing a capping layer on the aluminum-containing layer; exposing the substrate surface to a thermal treatment at a temperature of at least 700° C. to drive atoms of the interfacial silicon oxide layer into the high-κ metal oxide layer and to form a dipole region; and removing the high-κ barrier layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method for forming a metal gate stack in accordance with one or more embodiments of the disclosure;

FIG. 2 illustrates a cross-sectional view of a barrier layer on an underlying metal layer in accordance with one or more embodiments of the disclosure;

FIG. 3 illustrates a cross-sectional view of a metal gate stack in accordance with one or more embodiments of the disclosure;

FIG. 4 illustrates a cross-sectional view of a metal gate stack in accordance with one or more embodiments of the disclosure and

FIG. 5 illustrates a schematic top-view diagram of an example multi-chamber processing system in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, the term “in situ” refers to processes of method 100 that are all performed in the same processing chamber or within different processing chambers that are connected as part of a processing system, such that each of the processes of method 100 are performed without an intervening vacuum break. As used herein, the term “ex situ” refers to processes of method 100 that are performed in at least two different processing chambers such that one or more of the processes of method 100 are performed with an intervening vacuum break. In some embodiments, the method 100 is performed without breaking vacuum or without exposure to ambient air.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Field effect transistors are voltage-controlled devices where its current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated IS and current entering the channel at the drain (D) is designated ID. Drain-to-source voltage is designated VDS. By applying voltage to gate (G), the current entering the channel at the drain (i.e., ID) can be controlled.

The metal-oxide-semiconductor field-effect transistor (MOSFET) is a type of field-effect transistor (FET) and is used in integrated circuits and high-speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both be of the same type, and of opposite type to the body region. The source and drain (unlike the body) are highly doped as signified by a “+” sign after the type of doping.

If the MOSFET is an n-channel or nMOS FET, then the source and drain are n+regions and the body is a p-type substrate region. If the MOSFET is a p-channel or pMOS FET, then the source and drain are p+regions and the body is a n-type substrate region. The source is so named because it is the source of the charge carriers (electrons for n-channel, holes for p-channel) that flow through the channel; similarly, the drain is where the charge carriers leave the channel.

A nMOS FET, is made up of a n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode and saturation. Circuits with NMOS logic gates dissipate static power when the circuit is idling, since DC current flows through the logic gate when the output is low.

A pMOS FET is made up of p-type source and drain and a n-type substrate. When a positive voltage is applied between the source and the gate (negative voltage between gate and source), a p-type channel is formed between the source and the drain with opposite polarities. A current is carried by holes from source to the drain through an induced p-type channel. A high voltage on the gate will cause a PMOS not to conduct, while a low voltage on the gate will cause it to conduct. Logic gates and other digital devices implemented using PMOS are said have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices. Furthermore, NMOS ICs would be smaller than PMOS ICs (that give the same functionality), since the NMOS can provide one-half of the impedance provided by a PMOS (which has the same geometry and operating conditions).

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nano-wires or nano-slabs or nano-sheets, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

One or more embodiments of the present disclosure provide devices and methods of formation that are particularly useful in forming metal gate stacks (e.g., high-κ metal gate (HKMG) stacks) and will be described in that context. Other devices and applications are also within the scope of the invention.

Embodiments of the present disclosure advantageously provide methods of preventing aluminum diffusion in a metal gate stack (e.g., a high-κ metal gate (HKMG) stack). Additional embodiments of the present disclosure advantageously provide methods of forming metal gate stacks. Further embodiments of the present disclosure advantageously provide a barrier layer for improving threshold voltage (Vₜ) and substantially preventing leakage in metal gate stacks.

In some embodiments, the metal gate stack comprises an interfacial silicon oxide layer on a substrate surface; a high-κ metal oxide layer on the interfacial silicon oxide layer; a high-κ barrier layer on the high-κ metal oxide layer; and an aluminum-containing layer on the high-κ barrier layer.

The embodiments of the disclosure are described by way of the Figures, which illustrate devices (e.g., metal gate stacks) and processes for forming metal gate stacks in accordance with one or more embodiments of the disclosure. The processes shown are merely illustrative possible uses for the disclosed processes, and the skilled artisan will recognize that the disclosed processes are not limited to the illustrated applications.

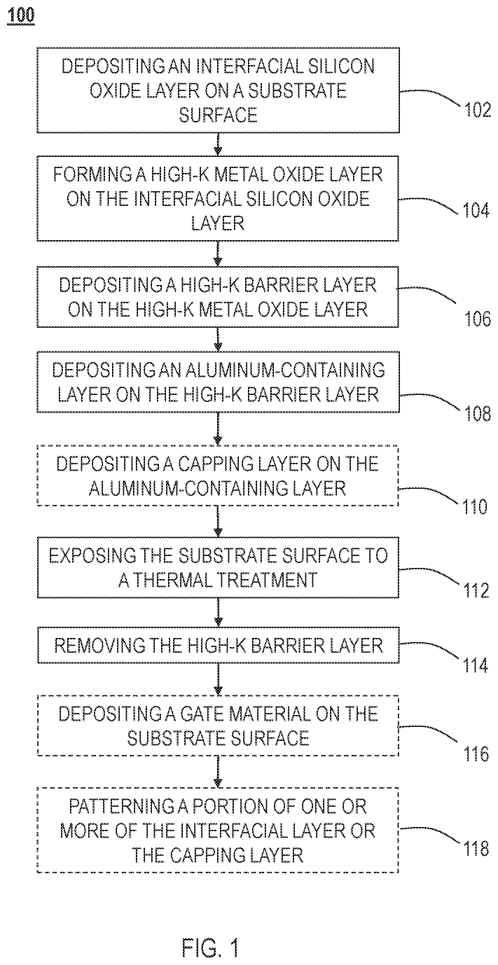

FIG. 1 illustrates a process flow diagram of a method 100 for forming a metal gate stack. The method 100, at operation 102, comprises depositing an interfacial silicon oxide layer on a substrate surface. At operation 104, the method 100 includes forming a high-κ metal oxide layer on the interfacial silicon oxide layer. At operation 106, the method 100 includes depositing a high-κ barrier layer on the high-κ metal oxide layer. At operation 108, the method 100 includes depositing an aluminum-containing layer on the high-κ barrier layer. The method 100, at operation 110, optionally includes depositing a capping layer on the aluminum-containing layer. At operation 112, the method 100 includes exposing the substrate surface to a thermal treatment. At operation 114, the method 100 includes removing the high-κ barrier layer. The method 100, at operation 116, optionally includes depositing a gate material on the substrate surface. The method 100, at operation 118, optionally includes patterning a portion of one or more of the interfacial layer or the capping layer.

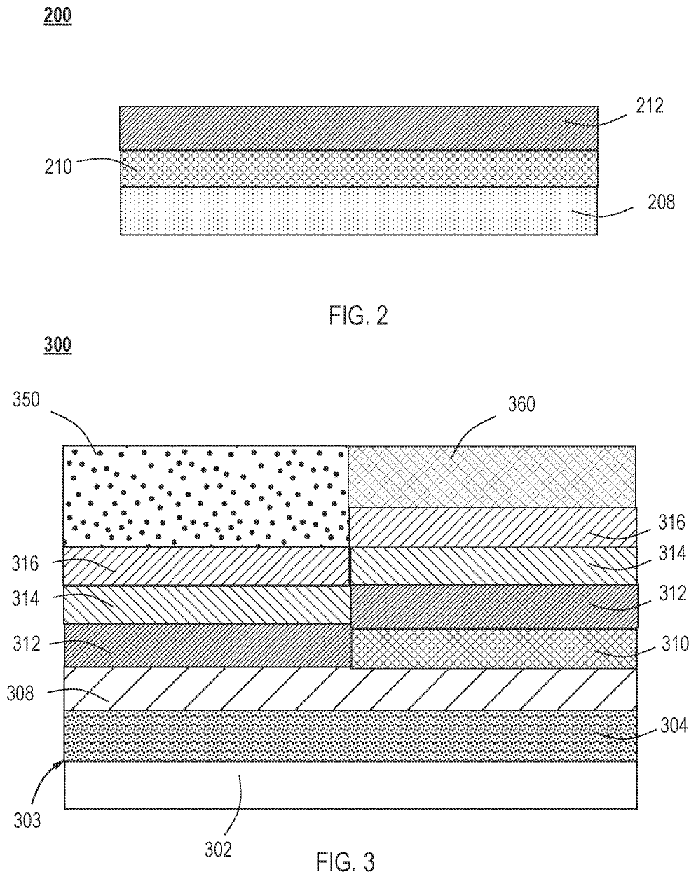

FIG. 2 illustrates a cross-sectional view of a film structure 200. In some embodiments, the film structure 200 comprises a high-κ barrier layer 210 on an underlying metal layer 208. The film structure 200 further comprises an aluminum-containing layer 212 on the high-κ barrier layer 210. It has been advantageously found that no aluminum or substantially no aluminum from the aluminum-containing layer 212 migrates through the high-κ barrier layer 210 into the underlying metal layer 208. As used in this context, “substantially no aluminum” means that the amount of aluminum that migrates through the high-κ barrier layer 210 into the underlying metal layer 208 is below the detection limit for X-ray photoelectron spectroscopy (XPS). Without intending to be bound by any particular theory, the detection limit for XPS is in a range of from 0.1 at. % to 1.0 at. %. In embodiments where substantially no aluminum from the aluminum-containing layer 212 migrates through the high-κ barrier layer 210 into the underlying metal layer 208, the amount of aluminum that may be present is below the detection limit for XPS and does not affect the physical properties of the underlying metal layer 208. In embodiments where substantially no aluminum from the aluminum-containing layer 212 migrates through the high-κ barrier layer 210 into the underlying metal layer 208, the amount of aluminum that may be present is below the detection limit for XPS and does not affect the electrical performance of the film structure 200.

FIG. 3 illustrates a cross-sectional view of a metal gate stack 300 on a substrate 302 according to one or more embodiments. In some embodiments, FIG. 3 illustrates a metal gate stack that has been formed by the method 100 illustrated in FIG. 1. The metal gate stack comprises an interfacial layer 304 on a substrate 302 (i.e., a substrate surface 303); a high-κ metal oxide layer 308 on the interfacial layer 304; a high-κ barrier layer 310 on the high-κ metal oxide layer 308; and an aluminum-containing layer 312 on the high-κ barrier layer 310. The skilled artisan will recognize that metal gate stacks containing some or all of the mentioned layers are within the scope of the disclosure.

In some embodiments, the substrate surface 303 is oxidized to form the interfacial layer 304. The substate 302 may comprise any suitable material know to the skilled artisan. In some embodiments, the substrate 302 comprises silicon (Si).

Although a few examples of materials from which the substrate 302 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure. In some embodiments, the substrate 302 comprises additional electric elements and materials including but not limited to source regions, drain regions, conductive channels, and other electrical connectors.

In one or more embodiments, the semiconductor substrate 302 is a p-type or n-type substrate. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

In one or more unillustrated embodiments, a source region is on the substrate surface 303 of the substrate 302. In one or more embodiments, the source region has a source and a source contact. In one or more embodiments, drain region is on the substrate surface 303 of the substrate 302 opposite the source region. In one or more embodiments, the drain region has a drain and a drain contact. In some embodiments, the metal gate stack is on the substrate 302 having a conductive channel. In embodiments where the substrate has a conductive channel, a source region and a drain region, the metal gate stack is on the conductive channel portion of the substrate 302 and not on the source region or the drain region.

In one or more embodiments, the source region and/or the drain region (not shown) can be any suitable material known to the skilled artisan. In one or more embodiments, the source region and/or the drain region may have more than one layer. In one or more embodiments, the source region and the drain region may independently comprise one or more of copper (Cu), cobalt (Co), tungsten (W), titanium (Ti), molybdenum (Mo), nickel (Ni), ruthenium (Ru), silver (Ag), gold (Au), iridium (Ir), platinum (Pt), phosphorus (P), germanium (Ge), silicon (Si), aluminum (Al), or zirconium (Zr).

In one or more embodiments, the source contact and/or the drain contact may independently be selected from one or more of nitrogen (N), copper (Cu), cobalt (Co), tungsten (W), titanium (Ti), molybdenum (Mo), nickel (Ni), ruthenium (Ru), silver (Ag), gold (Au), iridium (Ir), tantalum (Ta), or platinum (Pt). In one or more embodiments, formation of the source contact and/or the drain contact is conducted by any suitable process known to the skilled artisan, including, but not limited to ALD, CVD, PVD, MBE, MOCVD, spin-on, or other insulating layer deposition techniques known to the skilled artisan.

In one or more unillustrated embodiments, a conductive channel is located between the source and the drain. In embodiments where the conductive channel is located between the source and the drain, the metal gate stack is on the conductive channel and not on the source region or the drain region.

Referring again to FIG. 3, the interfacial layer 304 may comprise any suitable material known to the skilled artisan. In one or more embodiments, the interfacial layer 304 comprises one or more of silicon oxide. In one or more specific embodiments, the interfacial layer 304 comprises silicon dioxide. As used herein, “interfacial layer 304” and “interfacial silicon oxide layer 304” may be used interchangeably unless specifically noted otherwise.

Formation of the interfacial layer 304 may include a suitable thermal oxidation process, such as an enhanced in situ steam generation (eISSG) process utilizing nitrous oxide (N₂O) gas. In one or more embodiments, the interfacial layer 304 is a thin amorphous silicon oxide (SiO₂) layer, having a thickness of between about 3 Å and about 10 Å, for example, about 5 Å, corresponding to one or more monolayers of silicon oxide (SiO₂). In some embodiments, the interfacial layer 304 may be formed by an in situ steam generation (ISSG) process utilizing H₂ and O₂ gases, or by a rapid thermal oxidation (RTO) process utilizing NH₃ and O₂ gases, or by a wet chemical oxide process (e.g., Standard Clean 1 (SC1) solution including NH₄OH (ammonium hydroxide), H₂O₂ (hydrogen peroxide), and H₂O (water)), or an ozone (O₃) wet chemistry process. The interfacial layer 304 may act as a nucleation layer of the high-κ metal oxide layer 308 to be deposited thereon.

In some embodiments, a high-κ metal oxide layer 308 is formed on the interfacial silicon oxide layer 304. The high-κ metal oxide layer 308 may comprise any suitable material known to the skilled artisan. The high-κ metal oxide layer 308 may be formed of a high-κ dielectric material, such as hafnium dioxide (HfO₂), zirconium dioxide (ZrO₂), ytterbium oxide (Y₂O₃), aluminum oxide (Al₂O₃), ternary high-κ dielectric film with the third element doped into the existing metal oxide high-κ dielectric host material, such as hafnium zirconium oxide (HfZrO), hafnium lanthanum oxide (HfLaO), hafnium titanium oxide (HfTiO). In one or more embodiments, the high-κ metal oxide layer 308 comprises one or more of hafnium oxide (HfO₂), hafnium oxynitride (HfON), hafnium zirconium oxide (HfZrO), hafnium zirconium oxynitride (HfZrON), hafnium silicon oxide (HfSiO), and hafnium silicon oxynitride (HfSiON). In one or more specific embodiments, the high-κ metal oxide layer 308 comprises hafnium oxide (HfO₂).

Many precursors are within the scope of the invention. Precursors may be a plasma, gas, liquid or solid at ambient temperature and pressure. However, within the ALD chamber, precursors are volatilized. Organometallic compounds or complexes include any chemical containing a metal and at least one organic group, such as alkyls, alkoxyls, alkylamidos, and anilides. Precursors can be comprised of organometallic and inorganic/halide compounds.

The order in which the substrate is exposed to the precursors can be varied. The exposures may repeat in a deposition cycle. Further, exposure to a precursor may be repeated within a single deposition cycle.

The deposition process may include an atomic layer deposition (ALD) process, in which a metal-containing precursor and an oxygen-containing precursor are alternately delivered to the interfacial layer 304. In some embodiments, the metal-containing precursor is purged prior to delivering the oxygen-containing precursor. The metal may be a transition metal, such as hafnium (Hf), zirconium (Zr), or titanium (Ti), a rare-earth metal, such as lanthanum (La), ytterbium (Yb), or yttrium (Y), an alkaline earth metal, such as strontium (Sr). For the oxidant, any oxygen-containing precursor may be used that may react with the metal. For example, the oxygen-containing precursor may be or include water, diatomic oxygen, ozone, a hydroxyl-containing precursor or alcohol, nitrogen-and-oxygen-containing precursors, plasma-enhanced oxygen including locally or remotely enhanced oxygen, or any other material including oxygen that may be incorporated with the metal to produce a layer of an oxide of the metal over the interfacial layer. In one example, the metal-containing precursor is hafnium tetrachloride (HfCl₄) and the oxidant is water (H₂O) to form a hafnium dioxide (HfO₂) layer. The ALD process may be performed at a temperature of between 200° C. and about 400° C., for example, about 270° C. The high-κ metal oxide layer 308, as deposited by the ALD process, may be amorphous and have a thickness in a range of from 10 Å to 30 Å, including in a range of from 12 Å to 28 Å, and in a range of from 15 Å to 25 Å.

In some embodiments, a high-κ barrier layer 310 is formed on the high-κ metal oxide layer 308. In some embodiments, the high-κ barrier layer 310 is formed in regions of the metal gate stack in which a dipole region is not formed. In the illustrated embodiment of FIG. 3, a dipole region 350 is shown on a side of the metal gate stack where the high-κ barrier layer 310 is not present. A non-dipole region is shown on a side of the metal gate stack where the high-κ barrier layer 310 is present. As used herein, a “non-dipole region” refers to an area or region in which a dipole moment has not been formed. The high-κ barrier layer 210 illustrated in FIG. 2 may have the same or similar properties as the high-κ barrier layer 310 illustrated in FIG. 3.

In some embodiments, the high-κ barrier layer 310 comprises one or more of amorphous silicon (a-Si), titanium silicon nitride (TiSiN), tantalum nitride (TaN), or titanium tantalum nitride (TiTaN). Without intending to be bound theory, amorphous silicon (a-Si), as an example, may provide less diffusion of atoms as compared to polycrystalline silicon which includes grain boundaries leading to greater diffusion.

The high-κ barrier layer 310 may be deposited by any suitable deposition method. In some embodiments, the high-κ barrier layer 310 is deposited by one or more of atomic layer deposition (ALD) or chemical vapor deposition (CVD). In one or more specific embodiments, the high-κ barrier layer 310 comprises titanium silicon nitride (TiSiN) deposited by ALD.

In general, any suitable titanium precursor can be used for a titanium-containing high-κ barrier layer 310. Thus, titanium precursors can include one or more of, but are not limited to TiCl₄, TiBr₄, TiI₄, TiF₄, or tetrakisdimethylamino titanium.

Examples of the silicon precursors are poly-silanes (SiₓH_{y}). For example, poly-silanes include disilane (Si₂H₆), trisilane (Si₃H₈), tetrasilane (Si₄H₁₀), isotetrasilane, neopentasilane (Si₅H₁₂), cyclopentasilane (Si₅H₁₀), hexasilane (C₆H₁₄), cyclohexasilane (Si₆H₁₂) or, in general, SiₓH_{y} with x=2 or more, and combinations thereof.

Additionally, any suitable nitrogen source precursor can be used. Examples include, but are not limited to, nitrogen gas, ammonia gas, N₂H₂ or N₂H₄.

In one or more specific embodiments, depositing the high-κ barrier layer 310 comprises sequential exposure to a titanium precursor, purge, silicon precursor, purge, nitrogen source precursor, purge. In one or more specific embodiments, depositing the high-κ barrier layer 310 comprises sequential exposure to a titanium precursor, purge, silicon precursor, purge, nitrogen source precursor, purge, and a second cycle comprising sequential exposure to titanium precursor, purge, silicon precursor, and purge.

In one or more specific embodiments, the high-κ barrier layer 310 comprises titanium silicon nitride (TiSiN) deposited by ALD. In one or more specific embodiments, the high-κ barrier layer 310 is deposited at a temperature in the range of 350° C. to 500° C. and at a pressure in the range of 2 Torr to 50 Torr.

In some embodiments, the high-κ barrier layer 310 has a thickness in a range of from 5 Å to 20 Å. The high-κ barrier layer 310 may physically and chemically protect the underlying high-κ metal oxide layer 308 during a subsequent thermal treatment process at operation 112.

In some embodiments, an aluminum-containing layer 312 is formed on the high-κ barrier layer 310. In some embodiments, the aluminum-containing layer 312 comprises one or more of an aluminum oxide or an aluminum nitride. In some embodiments, the aluminum-containing layer 312 comprises titanium aluminum nitride (TiAlN). In some embodiments, the aluminum-containing layer 312 has a thickness in a range of from 5 Å to 25 Å, including in a range of from 10 Å to 20 Å.

The high-κ barrier layer 310 advantageously prevents or substantially prevents leakage from the aluminum-containing layer 312 into the high-κ metal oxide layer 308.

In one or more embodiments, at operation 112 of method 100, the substrate surface 303 is exposed to a thermal treatment at a temperature of at least 700º C to drive atoms of the interfacial silicon oxide layer 304 into the high-κ metal oxide layer 308. In one or more embodiments, the thermal treatment of operation 112 does not form a dipole region where the high-κ barrier layer 310 is not present. For example, the thermal treatment of operation 112 is illustrated in FIG. 3 on the side where the high-κ barrier layer 310 is present by showing the non-dipole region 360. In one or more embodiments, the thermal treatment of operation 112 forms a dipole region 350 where the high-κ barrier layer 310 is not present. The thermal treatment of operation 112 comprises exposing the substrate surface 303 to a temperature of at least 700º C to drive atoms of the aluminum-containing layer 312 into an interface of the interfacial silicon oxide layer 304 and the high-κ metal oxide layer 308 to form the dipole region 350. The dipole region 350 may comprise any suitable material known to the skilled artisan. In some embodiments, the dipole region 350 comprises atoms from each of the interfacial silicon oxide layer 304, the high-κ metal oxide layer 308 and the aluminum-containing layer 312. In some embodiments, the dipole region 350 comprises aluminum (Al), silicon oxide (SiO₂), and a high-κ dielectric material, such as hafnium dioxide (HfO₂), zirconium dioxide (ZrO₂), ytterbium oxide (Y₂O₃), aluminum oxide (Al₂O₃), ternary high-κ dielectric film with the third element doped into the existing metal oxide high-κ dielectric host material, such as hafnium zirconium oxide (HfZrO), hafnium lanthanum oxide (HfLaO), hafnium titanium oxide (HfTiO), hafnium oxide (HfO₂), hafnium oxynitride (HfON), hafnium zirconium oxide (HfZrO), hafnium zirconium oxynitride (HfZrON), hafnium silicon oxide (HfSiO), and hafnium silicon oxynitride (HfSiON). In some embodiments, the dipole region 350 comprises aluminum (Al), silicon oxide (SiO₂), and hafnium oxide (HfO₂).

In one or more embodiments, the thermal treatment of operation 112 comprises a post cap anneal (PCA) process, which is performed to harden and densify the at least one capping layer 314, 316. Crystallization of the as-deposited at least one capping layer 314, 316 may occur. The PCA process may comprise an anneal process. The anneal process may include a thermal anneal process in an inert ambient, such as in a nitrogen (N₂) and argon (Ar) ambient, performed in a rapid thermal processing (RTP) chamber, such as RADOX™ chamber, available from Applied Materials, Inc., located in Santa Clara, Calif.

The thermal treatment of operation 112 may be performed for between about 1 second and about 180 seconds, at a temperature of between about 600° C. and about 1000° C., for example, about 850° C. and at a pressure of between about 0.1 Torr and 100 Torr.

The metal gate stack advantageously has a threshold voltage (Vₜ) improved relative to a metal gate stack comprising a comparative high-κ metal oxide layer without the high-κ barrier layer 310.

The method 100, at operation 110, optionally includes depositing at least one capping layer (i.e., a first capping layer 314 and/or a second capping layer 316) on the aluminum-containing layer 312. FIG. 3 illustrates the first capping layer 314 and the second capping layer 316 on the aluminum-containing layer 312. In one or more embodiments, the metal gate stack includes the interfacial silicon oxide layer 304, the high-κ metal oxide layer 308, the high-κ barrier layer 310, the aluminum-containing layer 312, the first capping layer 314 and the second capping layer 316.

The capping layer 314, 316 may comprise any suitable material known to the skilled artisan. In some embodiments, the first capping layer 314 comprises or consists essentially of in situ deposited titanium nitride (TiN).

In one or more embodiments, the at least one capping layer 314, 316 is deposited by atomic layer deposition (ALD). An exemplary process for depositing TiN includes exposing the substrate to a first precursor comprising Ti, and then to a second precursor comprising a nitrogen source to provide a TiN film. For the avoidance of doubt, no stoichiometric ratios are implied by the identification of materials disclosed herein. For example, a TiN material contains titanium and nitrogen. These elements may or may not be present at a 1:1 ratio. In some embodiments, the substrate is exposed to the precursors repeatedly to obtain a predetermined film thickness. In some embodiments, the substrate is maintained a temperature of about 200° C. to about 700° C. during the ALD process.

In general, any suitable titanium precursor can be used for the first capping layer 314. Thus, titanium precursors can include one or more of, but are not limited to TiCl₄, TiBr₄, TiI₄, TiF₄, or tetrakisdimethylamino titanium. Additionally, any suitable nitrogen source precursor can be used. Examples include, but are not limited to, nitrogen gas, ammonia gas, N₂H₂ or N₂H₄.

In some embodiments, the second capping layer 316 comprises or consists essentially of silicon (Si). As used herein, “consists essentially of” means that the stated elements compose greater than 95%, greater than 98%, greater than 99% or greater than 99.5% of the stated material on an atomic basis.

The capping layer 314, 316 may have any suitable thickness. In some embodiments, the thickness of the first capping layer 314 is less than or equal to 10 Å, which includes 10 Å±10%, 10 Å±5%, and/or 10 Å±1%. In some embodiments, the thickness of the second capping layer 316 is less than or equal to 15 Å, which includes 15 Å±10%, 15 Å±5%, and/or 15 Å±1%.

At operation 114, the high-κ metal barrier layer 310 may be removed. According to one or more embodiments, at operation 114, the high-κ metal barrier layer 310, and, at operation 118, any remaining portion of the interfacial layer 304 and/or the capping layer 314, 316 may be removed. The removal process may include any dry plasma etch process or wet etch process known to the skilled artisan. The resulting structure may include a high-κ metal oxide layer 308 with an aluminum-containing layer 312 thereon that can then be further processed to fit desired applications. In some embodiments, all of the layers of the metal gate stack above the high-κ metal oxide layer 308 may be removed. At operation 118, the high-κ metal barrier layer 310 and the aluminum-containing layer 312 may be removed. In some embodiments, the resulting structure may include the high-κ metal oxide layer 308 on the interfacial layer 304. At operation 118, any remaining portion of the interfacial layer 304 may be removed, whereby the resulting structure may include the high-κ metal oxide layer 308 on the substrate 302.

As used herein, a “metal gate stack” refers to the layer or layers on the substrate 302. In one or more embodiments, the metal gate stack 300 includes the interfacial silicon oxide layer 304, the high-κ metal oxide layer 308, the high-κ barrier layer 310, and the aluminum-containing layer 312.

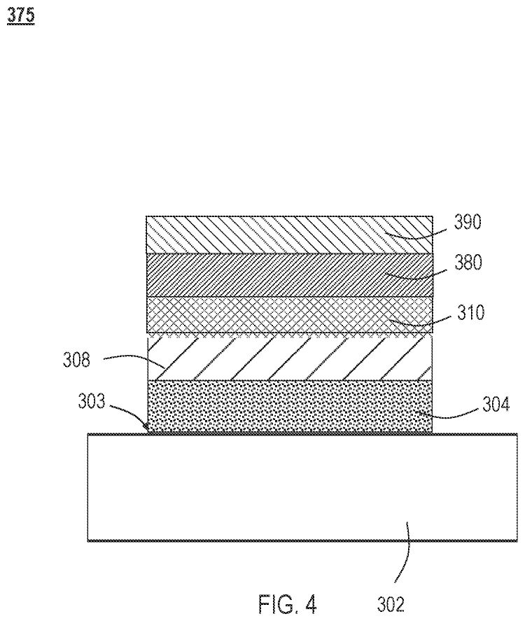

FIG. 4 illustrates a cross-sectional view of a metal gate stack (e.g., a nMOS FET metal gate stack 375) on a substrate 302 according to one or more embodiments. In some embodiments, FIG. 4 illustrates a nMOS FET metal gate stack 375 that has been formed by the method 100 illustrated in FIG. 1. In one or more unillustrated embodiments, the substrate 302 comprises an n-type channel between a source and a drain. Referring to FIG. 4, the nMOS FET metal gate stack 375 comprises an interfacial layer 304 on a substrate 302 (i.e., a substrate surface 303); a high-κ metal oxide layer 308 on the interfacial layer 304; a high-κ barrier layer 310 on the high-κ metal oxide layer 308; an n-type metal-containing layer 380 on the high-κ barrier layer 310 and an n-type metal capping layer 390 on the n-type metal-containing layer 380. In FIG. 4, the metal gate stack 375 includes the interfacial layer 304, the high-κ metal oxide layer 308, the high-κ barrier layer 310, the n-type metal-containing layer 380, and the n-type metal capping layer 390.

The n-type metal-containing layer 380 may comprise any suitable n-type metal known to the skilled artisan. In some embodiments, the n-type metal-containing layer 380 comprises titanium aluminum carbide (TiₓAlC). In some embodiments, the n-type metal-containing layer 380 comprises aluminum-doped titanium carbide.

The n-type metal capping layer 390 may comprise any suitable n-type metal capping layer material known to the skilled artisan. In some embodiments, the n-type metal capping layer 390 has the same or similar properties as the first capping layer 314 and/or the second capping layer 316. In some embodiments, the n-type metal capping layer 390 comprises one or more of titanium nitride (TiN), titanium silicon nitride (TiSiN), or silicon (Si). In some embodiments, the n-type metal capping layer 390 comprises or consists essentially of in situ deposited titanium nitride (TiN). In some embodiments, the n-type metal capping layer 390 comprises or consists essentially of silicon (Si).

Methods of this disclosure can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, a suitable processing apparatus may comprise multiple chambers in communication with a transfer station. An apparatus of this sort may be referred to as a “multi-chamber processing system.”

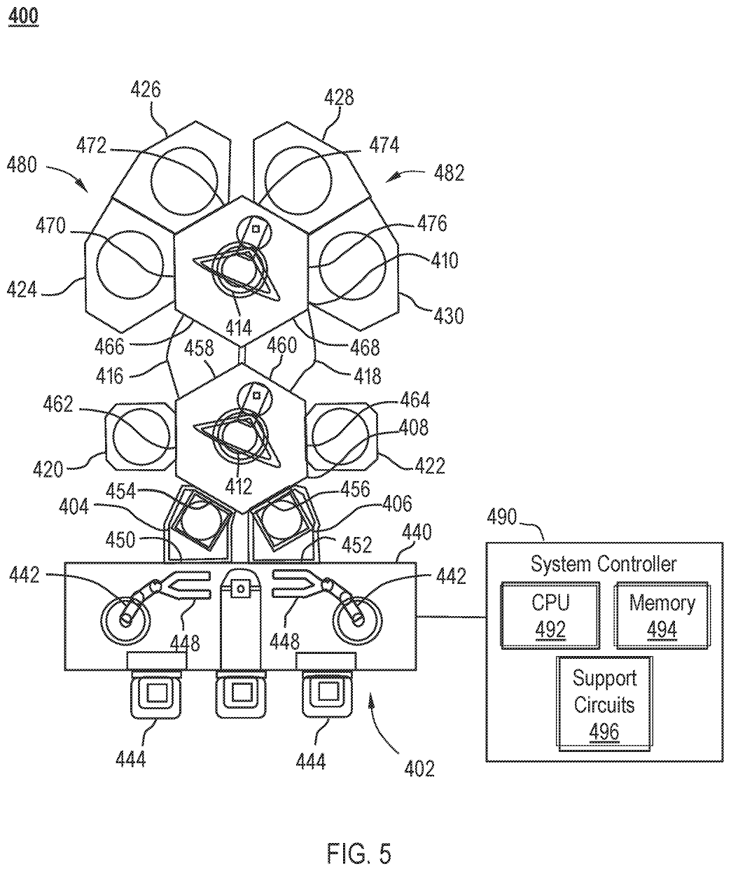

FIG. 5 illustrates a schematic top-view diagram of an example of a multi-chamber processing system 400 according to embodiments of the present disclosure. The processing system 400 generally includes a factory interface 402, load lock chambers 404, 406, transfer chambers 408, 410 with respective transfer robots 412, 414, holding chambers 416, 418, and processing chambers 420, 422, 424, 426, 428, 430. As detailed herein, wafers in the processing system 400 can be processed in and transferred between the various chambers without exposing the wafers to an ambient environment exterior to the processing system 400 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 400. Accordingly, the processing system 400 may provide for an integrated solution for some processing of wafers.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 5, the factory interface 402 includes a docking station 440 and factory interface robots 442 to facilitate transfer of wafers. The docking station 440 is configured to accept one or more front opening unified pods (FOUPs) 444. In some examples, each factory interface robot 442 generally comprises a blade 448 disposed on one end of the respective factory interface robot 442 configured to transfer the wafers from the factory interface 402 to the load lock chambers 404, 406.

The load lock chambers 404, 406 have respective ports 450, 452 coupled to the factory interface 402 and respective ports 454, 456 coupled to the transfer chamber 408. The transfer chamber 408 further has respective ports 458, 460 coupled to the holding chambers 416, 418 and respective ports 462, 464 coupled to processing chambers 420, 422. Similarly, the transfer chamber 410 has respective ports 466, 468 coupled to the holding chambers 416, 418 and respective ports 470, 472, 474, 476 coupled to processing chambers 424, 426, 428, 430. The ports 454, 456, 458, 460, 462, 464, 466, 468, 470, 472, 474, 476 can be, for example, slit valve openings with slit valves for passing wafers therethrough by the transfer robots 412, 414 and for providing a seal between respective chambers to prevent a gas from passing between the respective chambers. Generally, any port is open for transferring a wafer therethrough. Otherwise, the port is closed.

The load lock chambers 404, 406, transfer chambers 408, 410, holding chambers 416, 418, and processing chambers 420, 422, 424, 426, 428, 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 444 through a port 450 or 452 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the wafer between, for example, the atmospheric environment of the factory interface 402 and the low pressure or vacuum environment of the transfer chamber 408.

With the wafer in the load lock chamber 404 or 406 that has been pumped down, the transfer robot 412 transfers the wafer from the load lock chamber 404 or 406 into the transfer chamber 408 through the port 454 or 456. The transfer robot 412 is then capable of transferring the wafer to and/or between any of the processing chambers 420, 422 through the respective ports 462, 464 for processing and the holding chambers 416, 418 through the respective ports 458, 460 for holding to await further transfer. Similarly, the transfer robot 414 is capable of accessing the wafer in the holding chamber 416 or 418 through the port 466 or 468 and is capable of transferring the wafer to and/or between any of the processing chambers 424, 426, 428, 430 through the respective ports 470, 472, 474, 476 for processing and the holding chambers 416, 418 through the respective ports 466, 468 for holding to await further transfer. The transfer and holding of the wafer within and among the various chambers can be in the low pressure or vacuum environment provided by the gas and pressure control system.

The processing chambers 420, 422, 424, 426, 428, 430 can be any appropriate chamber for processing a wafer. In some embodiments, the processing chamber 420 can be capable of performing an annealing process, the processing chamber 422 can be capable of performing a cleaning process, and the processing chambers 424, 426, 428, 430 can be capable of performing epitaxial growth processes. In some examples, the processing chamber 422 can be capable of performing a cleaning process, the processing chamber 420 can be capable of performing an etch process, and the processing chambers 424, 426, 428, 430 can be capable of performing respective epitaxial growth processes. The processing chamber 422 may be a SiCoNi™ Preclean chamber available from Applied Materials of Santa Clara, Calif. The processing chamber 420 may be a Selectra™ Etch chamber available from Applied Materials of Santa Clara, Calif.

A system controller 490 is coupled to the processing system 400 for controlling the processing system 400 or components thereof. For example, the system controller 490 may control the operation of the processing system 400 using a direct control of the chambers 404, 406, 408, 416, 418, 410, 420, 422, 424, 426, 428, 430 of the processing system 400 or by controlling controllers associated with the chambers 404, 406, 408, 416, 418, 410, 420, 422, 424, 426, 428, 430. In operation, the system controller 490 enables data collection and feedback from the respective chambers to coordinate performance of the processing system 400.

The system controller 490 generally includes a central processing unit (CPU) 492, memory 494, and support circuits 496. The CPU 492 may be one of any form of a general-purpose processor that can be used in an industrial setting. The memory 494, or non-transitory computer-readable medium, is accessible by the CPU 492 and may be one or more of memory such as random-access memory (RAM), read only memory (ROM), floppy disk, hard disk, or any other form of digital storage, local or remote. The support circuits 496 are coupled to the CPU 492 and may comprise cache, clock circuits, input/output subsystems, power supplies, and the like. The various methods disclosed herein may generally be implemented under the control of the CPU 492 by the CPU 492 executing computer instruction code stored in the memory 494 (or in memory of a particular process chamber) as, for example, a software routine. When the computer instruction code is executed by the CPU 492, the CPU 492 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

The controller 990 of some embodiments has one or more configurations selected from: a configuration to deposit an interfacial silicon oxide layer on a substrate surface; a configuration to form a high-κ metal oxide layer on the interfacial silicon oxide layer; a configuration to deposit a high-κ barrier layer on the high-κ metal oxide layer; a configuration to deposit an aluminum-containing layer on the high-κ barrier layer; a configuration to deposit a capping layer on the aluminum-containing layer; a configuration to expose the substrate surface to a thermal treatment at a temperature of at least 700º C to drive atoms of the interfacial silicon oxide layer into the high-κ metal oxide layer; a configuration to expose the substrate surface to a thermal treatment at a temperature of at least 700º C to drive atoms of the aluminum-containing layer into an interface of the interfacial silicon oxide layer and the high-κ metal oxide layer to form the dipole region; and a configuration to remove the high-κ barrier layer.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of preventing aluminum diffusion in a metal gate stack, the method comprising:
forming a high-κ barrier layer on an underlying metal layer, the high-κ barrier layer comprising one or more of amorphous silicon (a-Si), titanium silicon nitride (TiSiN), tantalum nitride (TaN) or titanium tantalum nitride (TiTaN), the high-κ barrier layer having a thickness in the range of 5 Å to 30 Å; and
depositing an aluminum-containing layer on the high-κ barrier layer,
wherein substantially no aluminum from the aluminum-containing layer migrates through the high-κ barrier layer into the underlying metal layer.

2. The method of claim 1, wherein the high-κ barrier layer allows less aluminum to migrate into the underlying metal layer than a comparable titanium nitride (TiN) barrier layer.

3. A metal gate stack comprising:
an interfacial silicon oxide layer on a substrate surface;
a high-κ metal oxide layer on the interfacial silicon oxide layer;
a high-κ barrier layer on the high-κ metal oxide layer; and
an aluminum-containing layer on the high-κ barrier layer.

4. The metal gate stack of claim 3, wherein the high-κ metal oxide layer comprises hafnium oxide (HfO₂), hafnium oxynitride (HfON), hafnium zirconium oxide (HfZrO), hafnium zirconium oxynitride (HfZrON), hafnium silicon oxide (HfSiO), and hafnium silicon oxynitride (HfSiON).

5. The metal gate stack of claim 3, wherein the high-κ barrier layer comprises one or more of amorphous silicon (a-Si), titanium silicon nitride (TiSiN), tantalum nitride (TaN), or titanium tantalum nitride (TiTaN).

6. The metal gate stack of claim 5, wherein the high-κ barrier layer has a thickness in a range of from 5 Å to 20 Å.

7. The metal gate stack of claim 3, further comprising at least one capping layer on the aluminum-containing layer.

8. The metal gate stack of claim 7, wherein the at least one capping layer comprises a first capping layer and a second capping layer.

9. The metal gate stack of claim 8, wherein the first capping layer comprises in situ deposited titanium nitride (TiN).

10. The metal gate stack of claim 8, wherein the second capping layer comprises silicon (Si).

11. The metal gate stack of claim 8, wherein the first capping layer has a thickness of less than or equal to 10 Å and the second capping layer has a thickness of less than or equal to 15 Å.

12. The metal gate stack of claim 3, wherein the metal gate stack has a threshold voltage (Vₜ) improved relative to a metal gate stack comprising a comparative high-κ metal oxide layer without the high-κ barrier layer.

13. The metal gate stack of claim 3, wherein the high-κ barrier layer prevents or substantially prevents leakage from the aluminum-containing layer into the high-κ metal oxide layer.

14. A method of forming a metal gate stack, the method comprising:
depositing an interfacial silicon oxide layer on a substrate surface;
forming a high-κ metal oxide layer on the interfacial silicon oxide layer;
depositing a high-κ barrier layer on the high-κ metal oxide layer;
depositing an aluminum-containing layer on the high-κ barrier layer;
optionally depositing a capping layer on the aluminum-containing layer;
exposing the substrate surface to a thermal treatment at a temperature of at least 700º C to drive atoms of the interfacial silicon oxide layer into the high-κ metal oxide layer and to form a dipole region; and
removing the high-κ barrier layer.

15. The method of claim 14, wherein the high-κ barrier layer comprises one or more of amorphous silicon (a-Si), titanium silicon nitride (TiSiN), tantalum nitride (TaN), or titanium tantalum nitride (TiTaN).

16. The method of claim 14, wherein the metal gate stack has a threshold voltage (Vₜ) improved relative to a metal gate stack comprising a comparative high-κ metal oxide layer without the high-κ barrier layer.

17. The method of claim 14, wherein the high-κ barrier layer prevents or substantially prevents leakage from the aluminum-containing layer into the high-κ metal oxide layer.

18. The method of claim 14, wherein the capping layer comprises one or more of in situ deposited titanium nitride (TiN) or silicon (Si).

19. The method of claim 14, further comprising depositing a gate material on the substrate surface.

20. The method of claim 14, further comprising patterning any remaining portion of one or more of the interfacial silicon oxide layer or the optional capping layer.
